(19) United States
(12) Patent Application Publication
(10) Pub. No.: US 2025/0062266 A1
(43) Pub. Date: Feb. 20, 2025

(54) SEMICONDUCTOR PACKAGE

(71) Applicant: SAMSUNG ELECTRONICS CO., LTD., Suwon-si (KR)

(72) Inventors: Gyunghwan Oh, Suwon-si (KR); Sangmin Lee, Suwon-si (KR)

(21) Appl. No.: 18/653,664

(22) Filed: May 2, 2024

(30) Foreign Application Priority Data
Aug. 17, 2023 (KR) 10-2023-0107738

(51) Int. Cl. H01L 23/00; H01L 23/31; H01L 23/498; H01L 23/538; H01L 25/10

(52) U.S. Cl. CPC H01L 24/20; H01L 23/3107; H01L 23/49811; H01L 23/5385; H01L 23/5386; H01L 24/25; H01L 25/105; H01L 2224/214; H01L 2224/2518

(57) ABSTRACT

A semiconductor package includes a redistribution substrate including a first surface and a second surface which are opposite to each other, a semiconductor chip on the first surface of the redistribution substrate, and a connection terminal on the second surface of the redistribution substrate. The redistribution substrate includes an insulating layer, a redistribution pattern in the insulating layer, and an under bump pattern between the redistribution pattern and the connection terminal. The under bump pattern includes a via portion penetrating the insulating layer and connected to the redistribution pattern, and a protrusion protruding into the insulating layer.

### CROSS-REFERENCE TO RELATED APPLICATION

This U.S. non-provisional patent application claims priority under 35 U.S.C. § 119 to Korean Patent Application No. 10-2023-0107738, filed on Aug. 17, 2023, in the Korean Intellectual Property Office, the entire contents of which are hereby incorporated by reference.

### BACKGROUND OF THE INVENTION

The present disclosure relates to a semiconductor package.

An integrated circuit chip may be formed in a semiconductor package to be compatible with an electronic product. In a typical semiconductor package, a semiconductor chip may be mounted on a printed circuit board and may be electrically connected to the printed circuit board through bonding wires or bumps. Various techniques for improving reliability of semiconductor packages and for miniaturizing semiconductor packages have been studied with the development of an electronic industry.

### SUMMARY

In some implementations, the disclosed devices and techniques may provide a semiconductor package with improved reliability.

In general, aspects of the subject matter described in this specification can be embodied in a semiconductor package including: a redistribution substrate including a first surface and a second surface which are opposite to each other, a semiconductor chip on the first surface of the redistribution substrate, and a connection terminal on the second surface of the redistribution substrate. The redistribution substrate may include an insulating layer, a redistribution pattern in the insulating layer, and an under bump pattern between the redistribution pattern and the connection terminal. The under bump pattern may include a via portion penetrating the insulating layer and connected to the redistribution pattern, and a protrusion protruding into the insulating layer.

Another general aspect can be embodied in a semiconductor package including: a redistribution substrate including a first surface and a second surface which are opposite to each other, a semiconductor chip on the first surface of the redistribution substrate, and a connection terminal on the second surface of the redistribution substrate. The redistribution substrate may include an insulating layer, a redistribution pattern in the insulating layer, and an under bump pattern between the redistribution pattern and the connection terminal. The insulating layer may include a via hole exposing the redistribution pattern, and a recess spaced apart from the via hole in a first direction parallel to the second surface of the redistribution substrate. The under bump pattern may fill the via hole and the recess.

Another general aspect can be embodied in a semiconductor package including: a lower semiconductor package, and an upper semiconductor package on the lower semiconductor package. The lower semiconductor package may include a lower redistribution substrate, an upper redistribution substrate on the lower redistribution substrate, and a semiconductor chip between the lower redistribution substrate and the upper redistribution substrate. The lower redistribution substrate may include a plurality of insulating layers, redistribution patterns disposed in the insulating layers, and an under bump metal (UBM) disposed on a lowermost insulating layer of the plurality of insulating layers. The under bump metal may include a seed/barrier pattern, and a conductive pattern on the seed/barrier pattern. The under bump metal may include a via portion penetrating the lowermost insulating layer so as to be in contact with one of the redistribution patterns, which is adjacent thereto in a vertical direction, and a protrusion protruding into the lowermost insulating layer. The protrusion may be spaced apart from the one redistribution pattern, and a height of the protrusion may be less than a height of the via portion.

### BRIEF DESCRIPTION OF THE DRAWINGS

FIG. 1 is a cross-sectional view illustrating an example of a semiconductor package.

FIG. 2 is a bottom view illustrating an example of an under bump pattern of a semiconductor package.

FIG. 3A is a cross-sectional view taken along a line I-I′ of FIG. 2.

FIG. 3B is a cross-sectional view taken along a line II-II′ of FIG. 2.

FIG. 4 is a cross-sectional view corresponding to the line I-I′ of FIG. 2.

FIG. 5 is a bottom view illustrating an example of an under bump pattern of a semiconductor package.

FIG. 6 is a cross-sectional view taken along a line III-III′ of FIG. 5.

FIGS. 7A, 7B, 7C, 7D, 7E, 7F, and 7G are cross-sectional views illustrating an example of a method of manufacturing a semiconductor package.

FIG. 8A is an enlarged view of a region ‘bb’ of FIG. 7B.

FIG. 8B is an enlarged view of a region ‘cc’ of FIG. 7C.

FIG. 8C is a plan view illustrating an example of a schematic shape of a mask pattern.

FIG. 8D is an enlarged view of a region ‘dd’ of FIG. 7D.

FIG. 8E is an enlarged view of a region ‘ee’ of FIG. 7E.

FIG. 8F is an enlarged view of a region ‘ff’ of FIG. 7F.

FIG. 9 is a cross-sectional view illustrating an example of a semiconductor package.

FIGS. 10A, 10B, 10C and 10D are cross-sectional views illustrating an example of a method of manufacturing a semiconductor package.

### DETAILED DESCRIPTION

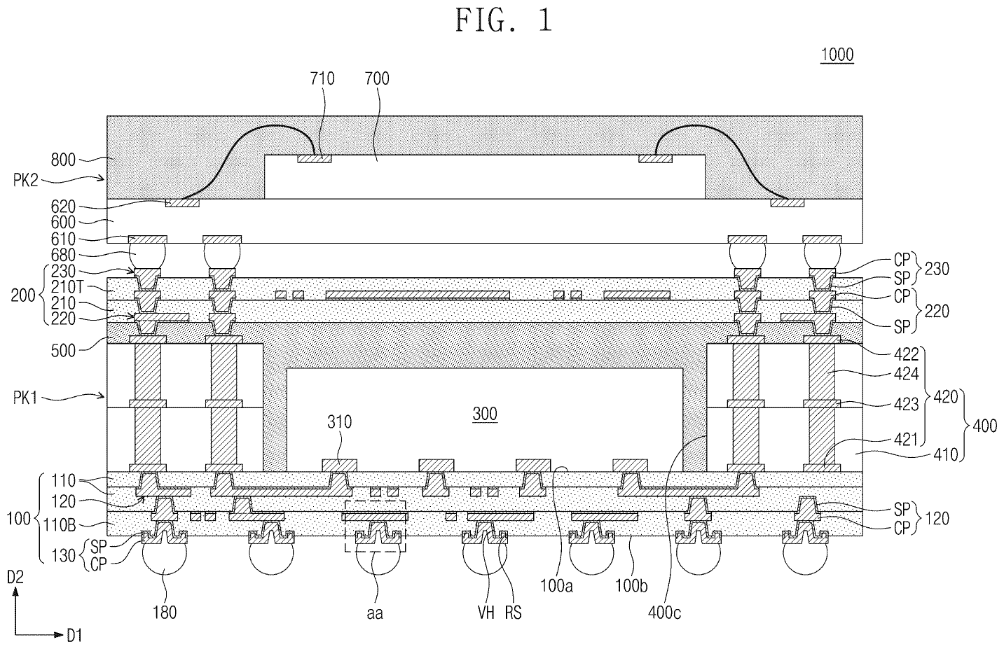

FIG. 1 is a cross-sectional view illustrating a semiconductor package.

Referring to FIG. 1, a semiconductor package 1000 includes a first semiconductor package PK1 and a second semiconductor package PK2 on the first semiconductor package PK1. The semiconductor package 1000 may have a package-on-package (POP) structure. In some implementations, the first semiconductor package PK1 and the second semiconductor package PK2 may be referred to as a lower semiconductor package PK1 and an upper semiconductor package PK2, respectively.

For example, the first semiconductor package PK1 may be a fan-out panel level package type semiconductor package.

The first semiconductor package PK1 may include a first redistribution substrate 100, a connection substrate 400, a first semiconductor chip 300, a second redistribution substrate 200, and a scaling member 500. In some implementations, the first redistribution substrate 100 and the second redistribution substrate 200 may be referred to as a lower redistribution substrate 100 and an upper redistribution substrate 200, respectively.

The first redistribution substrate 100 may include a plurality of first insulating layers 110 and 110B, first redistribution patterns 120, an under bump pattern 130, and an external connection terminal 180.

The first redistribution substrate 100 may have a first surface 100a and a second surface 100b, which are opposite to each other. The first surface 100a may mean a top surface of an uppermost first insulating layer 110 of the first insulating layers 110 and 110B. The second surface 100b may mean a bottom surface of a lowermost first insulating layer 110B of the first insulating layers 110 and 110B.

In some implementations, a first direction D1 may be defined as a direction parallel to the second surface 100b. A second direction D2 may be defined as a direction perpendicular to the second surface 100b.

Each of the first insulating layers 110 and 110B may include a photosensitive polymer. Each of the first insulating layers 110 and 110B may include at least one of photosensitive polyimide, polybenzoxazole, a phenol-based polymer, a benzocyclobutene-based polymer, or an Ajinomoto build-up film (ABF).

In some implementations, an interface between the first insulating layers 110 and 110B adjacent to each other may not be observed. In other words, the first insulating layers 110 and 110B may be observed as a single insulating layer.

Each of the first redistribution patterns 120 may include a seed/barrier pattern SP and a conductive pattern CP. The conductive pattern CP may be disposed on the seed/barrier pattern SP. The seed/barrier pattern SP may include copper (Cu)/titanium (Ti) or titanium nitride (TiN). The conductive pattern CP may include copper. In this disclosure, a “seed/barrier layer” is a layer that can function as either one of or both of a seed layer and a barrier layer.

A lowermost first redistribution pattern 120 of the first redistribution patterns 120 may be in contact with the under bump pattern 130. In some implementations, the under bump pattern 130 may be referred to as an under bump metal (UBM) or an under bump metallurgy (UBM). The under bump pattern 130 may include the seed/barrier pattern SP and the conductive pattern CP. A thickness of the seed/barrier pattern SP may range from 1 μm to 2 μm, and a thickness of the conductive pattern CP may range from 10 μm to 20 μm.

A shape of the under bump pattern 130 will be described below in detail. The external connection terminal 180 may be disposed on the under bump pattern 130. The external connection terminal 180 may include at least one of a solder ball, a pillar, or a bump. The external connection terminal 180 may include a conductive material such as tin (Sn) and/or silver (Ag).

The connection substrate 400 may be disposed on the first surface 100a of the first redistribution substrate 100. The connection substrate 400 may have a cavity 400c penetrating a central portion of the connection substrate 400. For example, the connection substrate 400 may be manufactured by forming the cavity 400c in a printed circuit board (PCB). The connection substrate 400 may include base layers 410 and a conductive structure 420.

Each of the base layers 410 may include at least one of a phenolic resin, a thermosetting resin (e.g., an epoxy resin), a thermoplastic resin (e.g., polyimide), or an insulating material obtained by impregnating the thermosetting or thermoplastic resin with a material (e.g., an inorganic filler and/or a glass fiber (or glass cloth or glass fabric)). For example, the base layer 410 may include at least one of prepreg, an Ajinomoto build-up film (ABF), frame retardant 4 (FR4), tetrafunctional epoxy, polyphenylene ether, bismaleimide triazine (BT), epoxy/polyphenylene oxide, thermount, cyanate ester, polyimide, or a liquid crystal polymer.

The conductive structure 420 may include a first connection pad 421, a second connection pad 422, a connection line 423, and a connection via 424.

The first connection pad 421 may be provided at a bottom surface of the connection substrate 400. The connection line 423 may be disposed between the base layers 410. The connection vias 424 may penetrate the base layers 410 to be connected to the connection line 423. The second connection pad 422 may be disposed on a top surface of the connection substrate 400 and may be connected to a corresponding one of the connection vias 424. The second connection pad 422 may be electrically connected to the first connection pad 421 through the connection vias 424 and the connection line 423. Unlike FIG. 1, the second connection pad 422 may not be aligned with the first connection pad 421 in the second direction D2. The number or arrangement of the second connection pads 422 may be different from the number or arrangement of the first connections pads 421. For example, each of the first connection pad 421, the second connection pad 422 and the connection line 423 may include at least one of electrolytically deposited (ED) copper foil, rolled-annealed (RA) copper foil, stainless steel foil, aluminum foil, ultra-thin copper foil, sputtered copper, or a copper alloy. The connection via 424 may include at least one of copper, nickel, stainless steel, or beryllium copper.

The first semiconductor chip 300 may be disposed in the cavity 400c of the connection substrate 400. More particularly, the first semiconductor chip 300 may be disposed on the first redistribution substrate 100 so that a first chip pad 310 of the first semiconductor chip 300 faces the first redistribution substrate 100. A horizontal cross-sectional area of the cavity 400c may be greater than a horizontal cross-sectional area of the first semiconductor chip 300. The first semiconductor chip 300 may be spaced apart from an inner side surface of the connection substrate 400 in the cavity 400c. The first semiconductor chip 300 may be a logic chip. For example, the first semiconductor chip 300 may be a central processing unit (CPU), a micro processing unit (MPU), a graphic processing unit (GPU), or an application processor (AP).

The sealing member 500 may fill a gap between the first semiconductor chip 300 and the inner side surface of the connection substrate 400. The sealing member 500 may cover a top surface of the first semiconductor chip 300 and the top surface of the connection substrate 400. The sealing member 500 may include a thermosetting resin (e.g., an epoxy resin), a thermoplastic resin (e.g., polyimide), or a resin formed by providing a reinforcing material (e.g., an inorganic filler) into the thermosetting or thermoplastic resin. For example, the sealing member 500 may include an Ajinomoto build-up film (ABF).

The second redistribution substrate 200 may be disposed on the sealing member 500. The second redistribution substrate 200 may include second insulating layers 210 and 210T, second redistribution patterns 220, and a bonding pad 230. The second insulating layers 210 and 210T may include the same/similar material as the first insulating layers 110 and 110B. A lowermost second redistribution pattern 220 of the second redistribution patterns 220 may be connected to or in contact with the second connection pad 422 of the connection substrate 400. The bonding pad 230 may be disposed on an uppermost second redistribution pattern 220 of the second redistribution patterns 220. For example, a top surface of the bonding pad 230 may protrude from a top surface of an uppermost second insulating layer 210T. Each of the second redistribution patterns 220 and the bonding pad 230 may include a seed/barrier pattern SP and a conductive pattern CP on the seed/barrier pattern SP and may include the same/similar material as the first redistribution patterns 120 and the under bump pattern 130.

The second semiconductor package PK2 may be provided on the second redistribution substrate 200. The second semiconductor package PK2 may include a package substrate 600, a second semiconductor chip 700, and a molding member 800. For example, the package substrate 600 may be a printed circuit board. A first metal pad 610 and a second metal pad 620 may be provided on a bottom surface and a top surface of the package substrate 600, respectively. For example, the second semiconductor chip 700 may be a memory chip such as a DRAM chip or a NAND FLASH chip. A kind of the second semiconductor chip 700 may be different from a kind of the first semiconductor chip 300. A second chip pad 710 disposed on a surface of the second semiconductor chip 700 may be connected to the second metal pad 620 of the package substrate 600 by a wire bonding method. In some implementations, the second semiconductor chip 700 may be connected to the package substrate 600 by a flip-chip bonding method, instead of the wire bonding method.

A package connection terminal 680 may be disposed between the first semiconductor package PK1 and the second semiconductor package PK2. The package connection terminal 680 may be in contact with the bonding pad 230 and the first metal pad 610. The package connection terminal 680 may electrically connect the first semiconductor package PK1 and the second semiconductor package PK2. For example, the second semiconductor chip 700 may be electrically connected to the first semiconductor chip 300 and the external connection terminal 180 through a bonding wire, the package substrate 600, the package connection terminal 680, the second redistribution substrate 200, the connection substrate 400 and the first redistribution substrate 100. The package connection terminal 680 may include at least one of a solder ball, a pillar, or a bump. The package connection terminal 680 may include a conductive material such as tin (Sn) and/or silver (Ag).

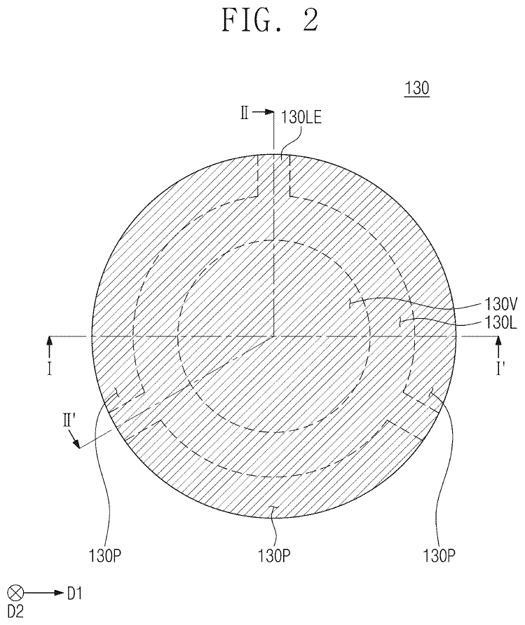

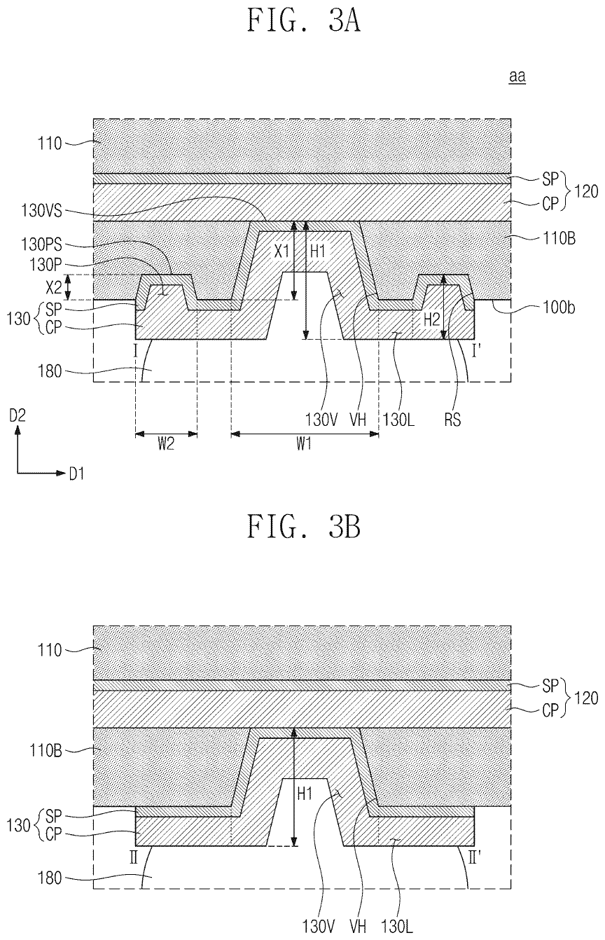

FIG. 2 is a bottom view illustrating an under bump pattern of a semiconductor package. FIG. 3A is a cross-sectional view taken along a line I-I′ of FIG. 2. FIG. 3A is an enlarged view of a region ‘aa’ of FIG. 1. FIG. 3B is a cross-sectional view taken along a line II-II′ of FIG. 2.

Referring to FIGS. 1, 2, 3A and 3B, the lowermost first insulating layer 110B of the first insulating layers 110 and 110B includes a via hole VH and a recess RS. The via hole VH and the recess RS may be spaced apart from each other in the first direction D1. The via hole VH may expose a bottom surface of the conductive pattern CP of the first redistribution pattern 120 adjacent thereto in the second direction D2. The recess RS may not expose the bottom surface of the conductive pattern CP of the first redistribution pattern 120, e.g., the recess RS is spaced apart and separate from the redistribution pattern 120. The via hole VH may have a first depth X1 in the second direction D2, and the recess RS may have a second depth X2 in the second direction D2. The second depth X2 may be less than the first depth X1. The second depth X2 may be greater than ⅛ of the first depth X1. In particular, the second depth X2 may be greater than ⅛ of the first depth X1 and may be less than ¼ of the first depth X1. For example, the first depth X1 may range from 20 μm to 30 μm, and the second depth X2 may range from 5 μm to 15 μm.

The under bump pattern 130 may fill the via hole VH and the recess RS and may laterally extend on the bottom surface, e.g., second surface 100b, of the lowermost first insulating layer 110B between the via hole VH and the recess RS. The seed/barrier pattern SP of the under bump pattern 130 may partially fill the via hole VH and the recess RS. The conductive pattern CP of the under bump pattern 130 may partially fill the via hole VH. The conductive pattern CP of the under bump pattern 130 may completely fill the recess RS. The under bump pattern 130 may include a via portion 130V, protrusions 130P, and a connection portion 130L. The connection portion 130L may connect the via portion 130V and the protrusions 130P. The under bump pattern 130 may have a W-shape or a W-like shape when viewed in a cross-sectional view. In this disclosure, a W-like shape can mean having a first horizontal portion connected to two slanted portions, e.g., via portion 130V on either end of the first horizontal portion, and second and third horizontal portions, e.g., connection portion 130L, on both ends of the two slanted portions, where the first horizontal portion has a greater height than the second and third horizontal portions.

The via portion 130V may include a portion of the seed/barrier pattern SP and a portion of the conductive pattern CP, which fill the via hole VH. The via portion 130V may penetrate the lowermost first insulating layer 110B to be in contact with the first redistribution pattern 120 adjacent thereto in the second direction D2. Like FIG. 2, the via portion 130V may have a circular shape when viewed in a plan view.

Each of the protrusions 130P may include another portion of the seed/barrier pattern SP and another portion of the conductive pattern CP, which fill the recess RS. The protrusion 130P may protrude into the lowermost first insulating layer 110B. The protrusion 130P may be spaced apart from the first redistribution pattern 120 adjacent thereto in the second direction D2. The protrusion 130P may be disposed at an edge of the under bump pattern 130. A level of a top surface 130PS of the protrusion 130P may be higher than a level of the bottom surface, e.g., second surface 100b, of the lowermost first insulating layer 110B and may be lower than a level of a top surface 130VS of the via portion 130V. Like FIG. 2, the protrusions 130P may constitute a segmented ring shape when viewed in a plan view. The protrusions 130P may surround the via portion 130V when viewed in a plan view.

The connection portion 130L may include a remaining portion of the seed/barrier pattern SP and a remaining portion of the conductive pattern CP, which are disposed on the, e.g., second surface bottom surface 100b, of the lowermost first insulating layer 110B. The connection portion 130L may be disposed between the via portion 130V and the protrusion 130P and may have a ring shape when viewed in a plan view, like FIG. 2. The connection portion 130L may include an extension 130LE extending between the protrusions 130P.

Comparing the via portion 130V with the protrusion 130P, the via portion 130V may have a first height H1, and the protrusion 130P may have a second height H2. The second height H2 may be less than the first height H1. The second height H2 may be greater than ⅛ of the first height H1. The via portion 130V and the protrusion 130P may be spaced apart from each other in the first direction D1.

The via portion 130V may have a first width W1 in the first direction D1, and the protrusion 130P may have a second width W2 in the first direction D1. The second width W2 may be less than the first width W1. For example, the second width W2 may range from 1/13 to 1/10 of the first width W1. For example, the first width W1 may range from 130 μm to 170 μm, and the second width W2 may range from 10 μm to 15 μm.

In a semiconductor package according to a comparative example, an under bump pattern 130 may not include a protrusion. At an operating temperature (e.g., −40 degrees Celsius to 85 degrees Celsius) of the semiconductor package according to the comparative example, stress (e.g., 5.5 GPa) may be strongly applied to an edge portion of the under bump pattern 130 and a lowermost first insulating layer 110B, which are in contact with each other, due to a thermal expansion coefficient difference therebetween. Thus, a crack may easily occur in the lowermost first insulating layer 110B. In addition, the under bump pattern 130 may be easily delaminated from a bottom surface of the lowermost first insulating layer 110B.

In some implementations, the under bump pattern 130 may include the protrusion 130P protruding into the lowermost first insulating layer 110B. As a result, a contact area between the under bump pattern 130 and the first insulating layer 110B may be increased.

In some implementations, the second height H2 of the protrusion 130P may be less than the first height H1 of the via portion 130V. If the second height H2 is equal to the first height H1, a portion of the lowermost first insulating layer 110B disposed between the via portion 130V and the protrusion 130P may be isolated from another portion of the lowermost first insulating layer 110B. In this case, stress resulting from thermal mismatch, e.g., different thermal expansion coefficient, is dispersed, and the stress density may be reduced. In addition, the second height H2 of the protrusion 130P may be greater than ⅛ of the first height H1 of the via portion 130V (or the second depth X2 may be greater than ⅛ of the first depth X1 of the via hole VH, e.g., 4 μm to 24 μm). For example, if the second height H2 is less than ⅛ of the first height H1, a contact area between the protrusion 130P and the first insulating layer 110B may be small, and thus an effect of reducing the stress may not be great (e.g., 4.3 Gpa). The effect of reducing the stress may increase as the second height H2 of the protrusion 130P increases, but the effect of reducing the stress may not be great when the second height H2 is ¼ or more of the first height H1 (e.g., 3.x Gpa).

In some implementations, the semiconductor package may include the under bump pattern 130 including the protrusion 130P, and thus the stress may be reduced by about 45% or more (e.g., 3.036 GPa) at an operating temperature (e.g., −40 degrees Celsius to 85 degrees Celsius) of the semiconductor package, as compared with the comparative example. As a result, an interface between the lowermost first insulating layer 110B and the under bump pattern 130 may be stabilized to improve reliability of the semiconductor package.

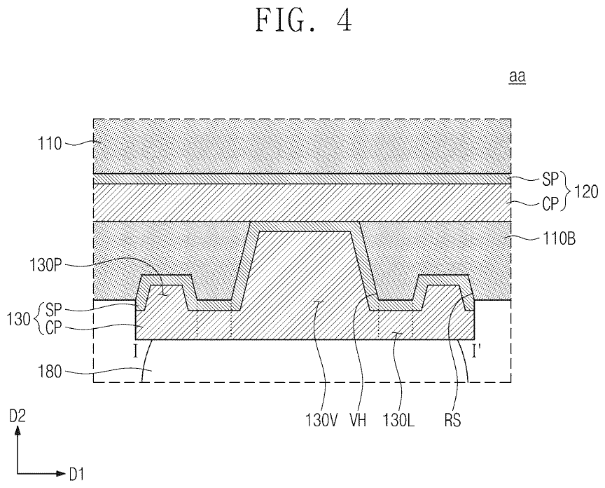

FIG. 4 is a cross-sectional view corresponding to the line I-I′ of FIG. 2. Hereinafter, the descriptions to the same features as mentioned with reference to FIGS. 1 to 3B will be omitted. Referring to FIG. 4, the conductive pattern CP of the under bump pattern 130 may completely fill a remaining portion of the via hole VH, which is not filled with the seed/barrier pattern SP.

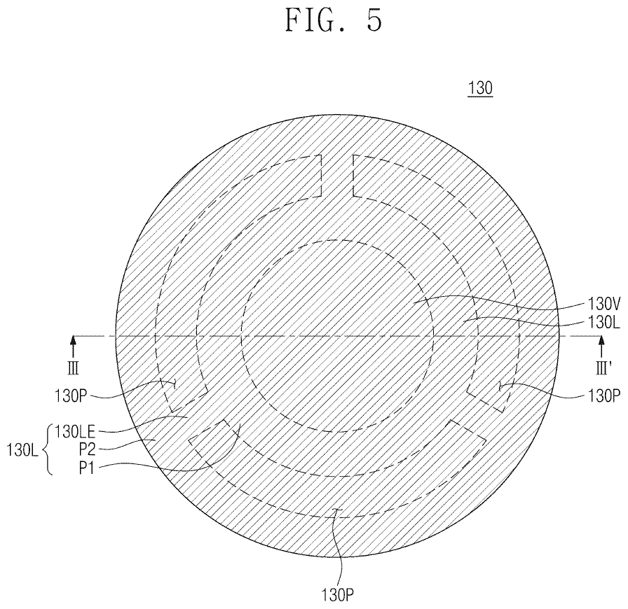

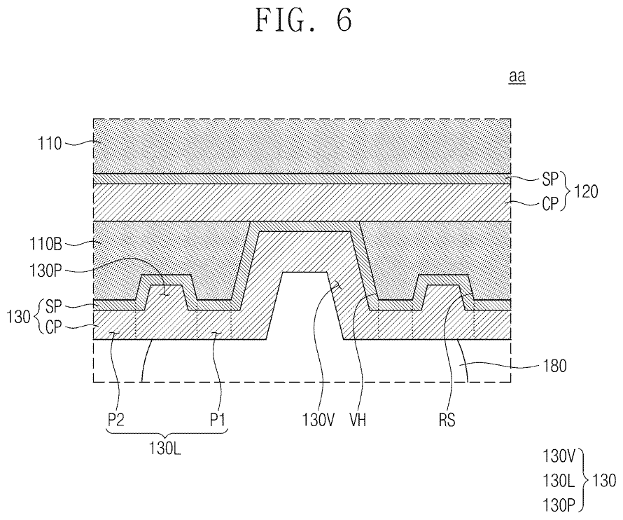

FIG. 5 is a bottom view illustrating an under bump pattern of a semiconductor package. FIG. 6 is a cross-sectional view taken along a line III-III′ of FIG. 5. Hereinafter, the descriptions to the same features as mentioned with reference to FIGS. 1 to 4 will be omitted. Referring to FIGS. 5 and 6, a connection portion 130L of the under bump pattern 130 may include a first portion P1 and a second portion P2. The first portion P1 may be disposed between the via portion 130V and the protrusion 130P. The second portion P2 may be connected to the first portion P1 with the protrusion 130P interposed therebetween. The first portion P1 and the second portion P2 may be connected to each other through an extension 130LE in a gap between the protrusions 130P.

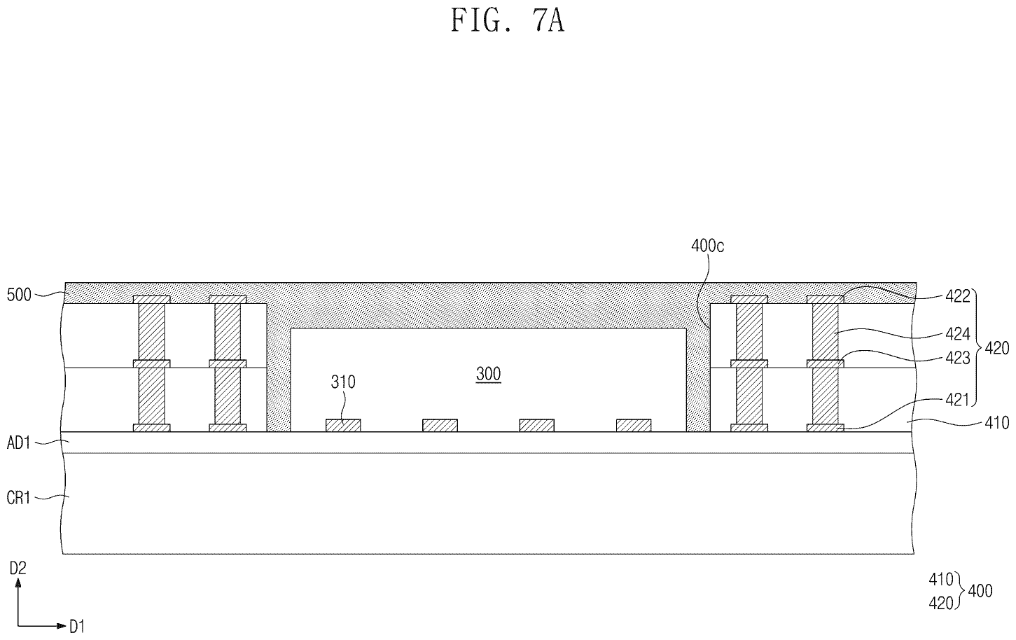

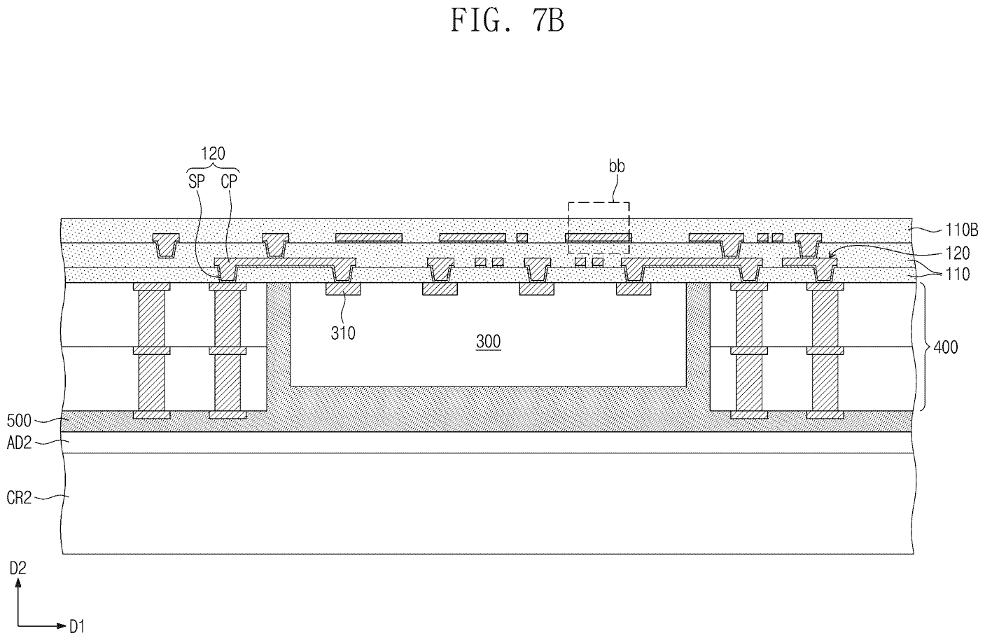

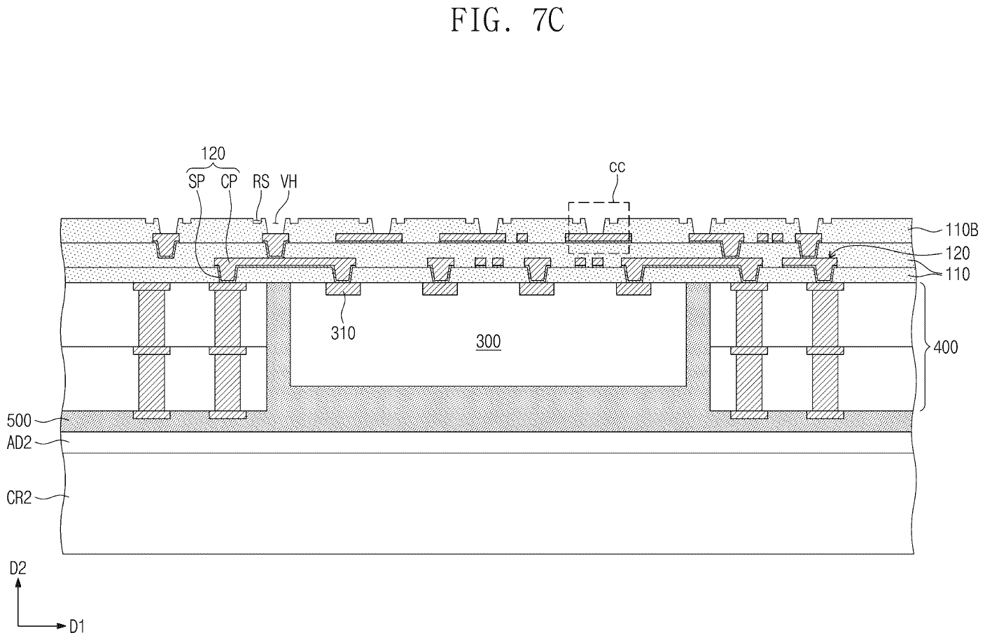

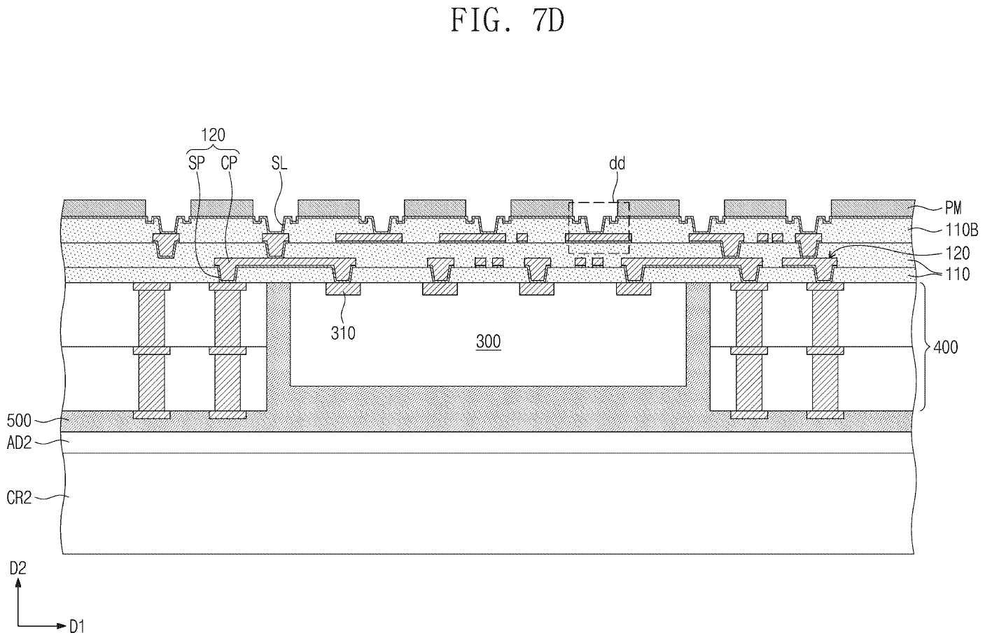

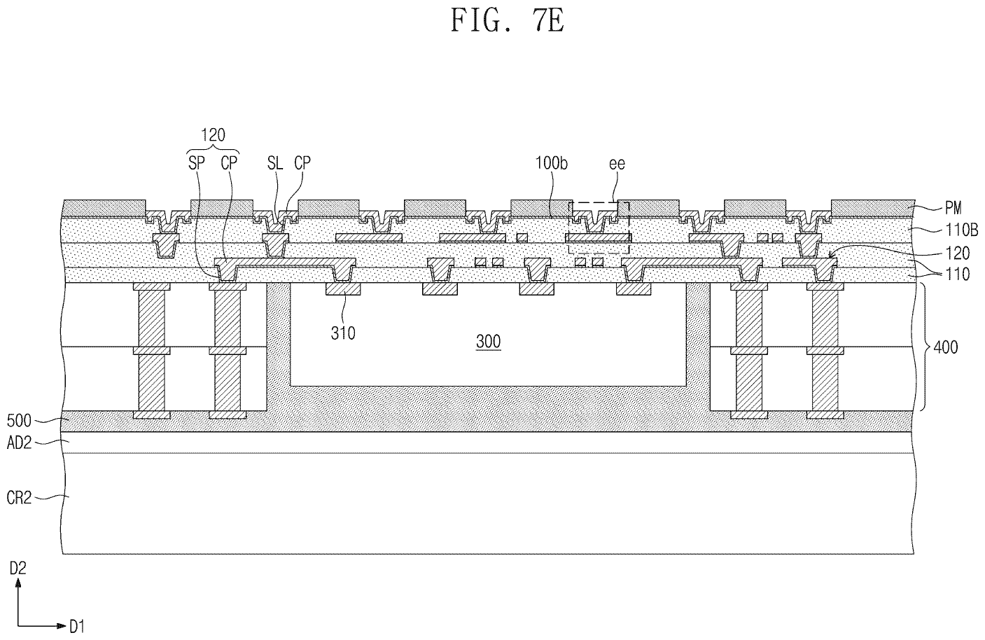

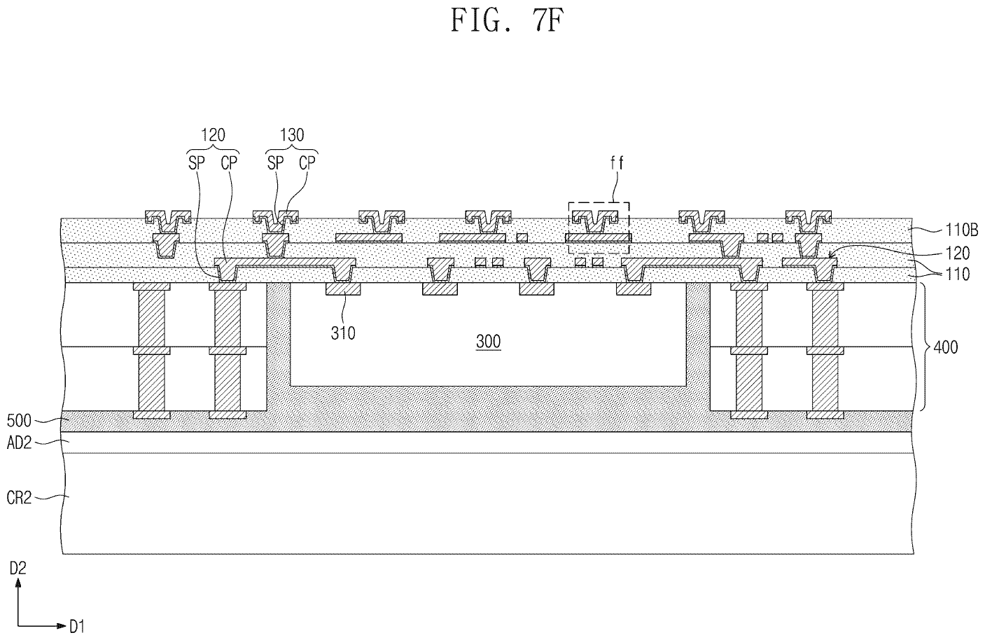

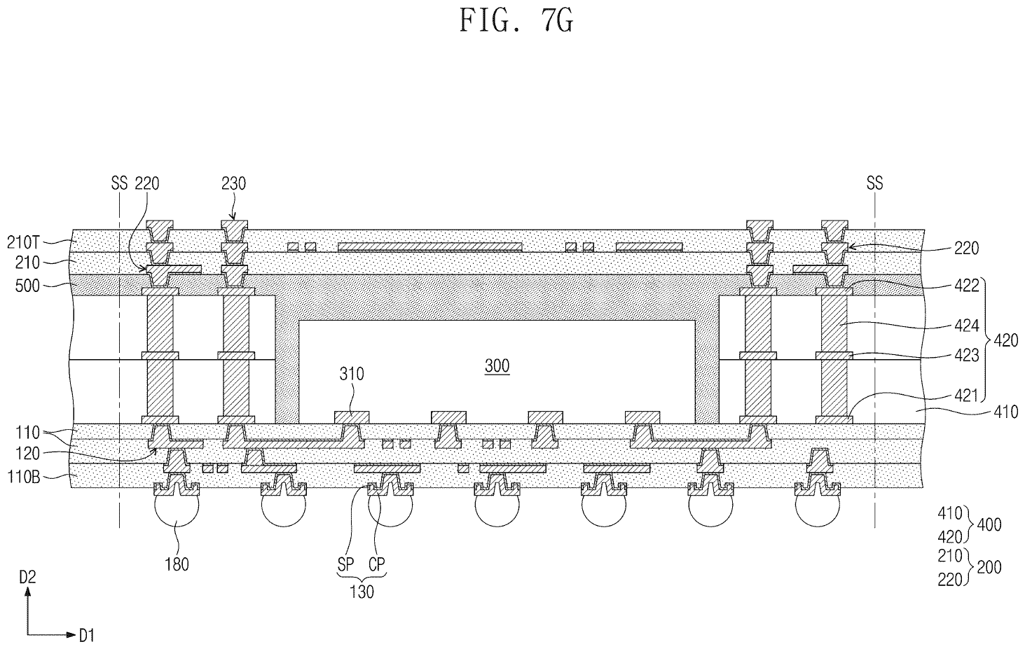

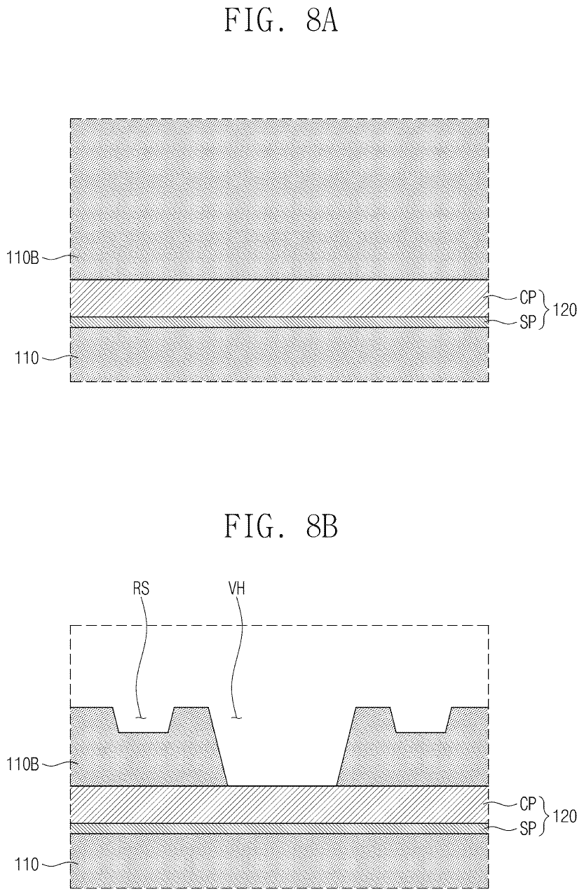

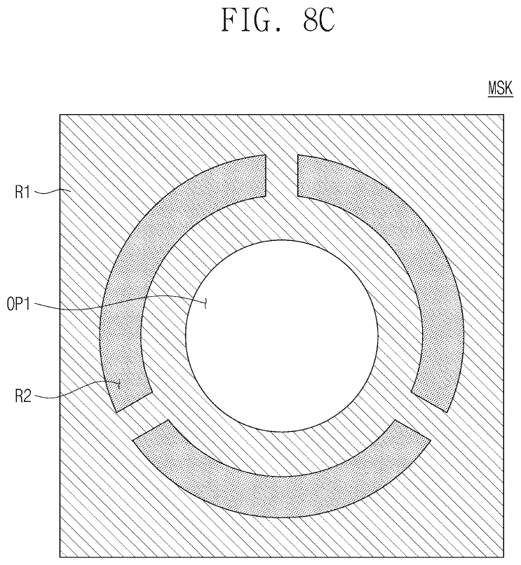

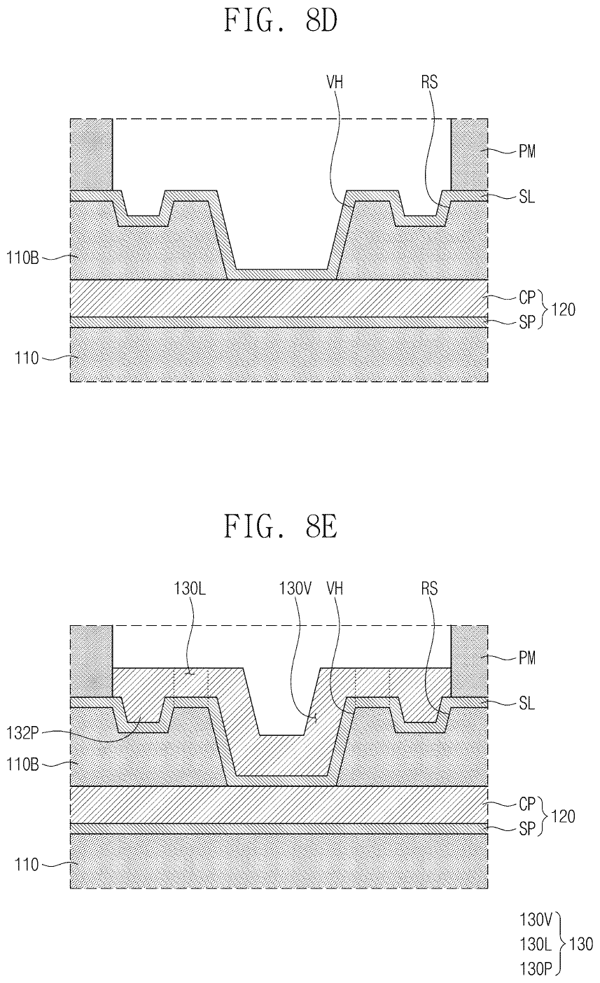

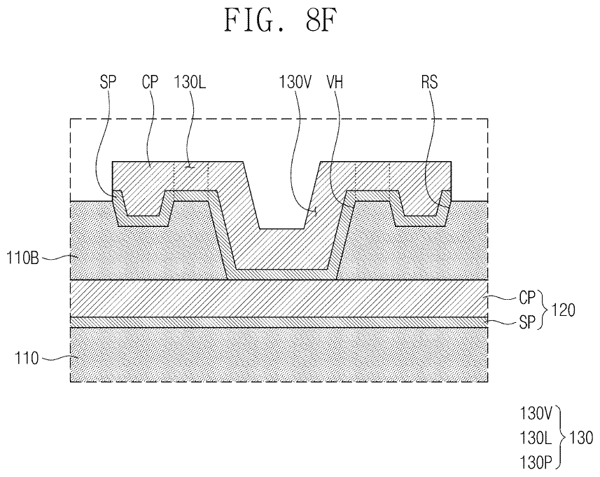

FIGS. 7A, 7B, 7C, 7D, 7E, 7F, and 7G are cross-sectional views illustrating a method of manufacturing a semiconductor package. FIG. 8A is an enlarged view of a region ‘bb’ of FIG. 7B. FIG. 8B is an enlarged view of a region ‘cc’ of FIG. 7C. FIG. 8C is a plan view illustrating a schematic shape of a mask pattern. FIG. 8D is an enlarged view of a region ‘dd’ of FIG. 7D. FIG. 8E is an enlarged view of a region ‘ee’ of FIG. 7E. FIG. 8F is an enlarged view of a region ‘ff’ of FIG. 7F.

Referring to FIG. 7A, a first carrier substrate CR1 having a surface on which a first adhesive layer AD1 is formed may be provided. A connection substrate 400 in which a cavity 400c is formed may be disposed on the first carrier substrate CR1. A first semiconductor chip 300 may be disposed in the cavity 400c. The first adhesive layer AD1 may adhere the connection substrate 400 and the first semiconductor chip 300 on the first carrier substrate CR1. A sealing member 500 may be formed in a space between the connection substrate 400 and the first semiconductor chip 300. For example, the formation of the sealing member 500 may include injecting an Ajinomoto build-up film (ABF) and applying heat to the injected Ajinomoto build-up film (ABF).

Referring to FIGS. 7B and 8A, a second carrier substrate CR2 and a second adhesive layer AD2 may be disposed to be in contact with the sealing member 500. In addition, the first adhesive layer AD1 and the first carrier substrate CR1 may be removed. In this process, the chip pad 310 of the first semiconductor chip 300 and the first connection pad 421 of the connection substrate 400 may be exposed. First insulating layers 110 and first redistribution patterns 120 may be formed on the first semiconductor chip 300 and the connection substrate 400. The first insulating layers 110 and the first redistribution patterns 120 may be formed as a multi-layered structure. Each of the first insulating layers 110 may be formed using coating, exposure, development and hardening processes of a photosensitive insulating material (e.g., a photo-imagable dielectric (PID) layer). The formation of each of the first redistribution patterns 120 may include forming a first seed/barrier layer on the first insulating layer 110, forming a first photo-mask pattern defining a formation space of a conductive pattern CP, forming the conductive pattern CP on the first seed/barrier layer by an electroplating method, removing the first photo-mask pattern, and patterning the first seed/barrier layer using the conductive pattern CP as an etch mask to form a seed/barrier pattern SP.

The formation of a lowermost first insulating layer 110B may include coating or forming a photosensitive insulating material (e.g., a photo-imagable dielectric (PID) layer) or an Ajinomoto build-up film (ABF) that covers a lowermost first redistribution pattern 120.

Referring to FIGS. 7C, 8B, and 8C, a mask pattern MSK including a first opening OP1 of FIG. 8C may be disposed on the lowermost first insulating layer 110B. The first opening OP1 may define a region in which a via hole VH of FIGS. 7C and 8B will be formed. The mask pattern MSK may include a first region R1 and a second region R2 in addition to the first opening OP1. For example, when light is irradiated to the mask pattern MSK, the first region R1 may not transmit the light, and the second region R2 may not transmit a certain percentage or more of the light. More particularly, the second region R2 may be a phase shift mask (PSM) and may reduce a contrast of the light passing through the second region R2. The second region R2 may define a region in which a recess RS of FIGS. 7C and 8B will be formed. Subsequently, a development process may be performed on the lowermost first insulating layer 110B. As a result of the development process, a portion of the lowermost first insulating layer 110B, which vertically overlapped with the first opening OP1 of the mask pattern MSK, may be removed to form the via hole VH. A portion of the lowermost first insulating layer 110B, which vertically overlapped with the second region R2 of the mask pattern MSK, may be removed to form the recess RS. A portion of the lowermost first insulating layer 110B, which vertically overlapped with the first region R1 of the mask pattern MSK, may not be removed. The amount of an insulating material of the first insulating layer 110B removed when forming the recess RS may be less than the amount of an insulating material of the first insulating layer 110B removed when forming the via hole VH. Next, a hardening process may be performed on the lowermost first insulating layer 110B.

Referring to FIGS. 7D and 8D, a second seed/barrier layer SL may be formed to partially fill the via hole VH and the recess RS. The second seed/barrier layer SL may cover an exposed surface of the lowermost first insulating layer 110B. A second photo-mask pattern PM may be formed on a top surface of the second seed/barrier layer SL. The second photo-mask pattern PM may include an opening defining a formation space of an under bump pattern 130. The second photo-mask pattern PM may be formed using coating, exposure, and development processes of a photoresist layer. The second seed/barrier layer SL may be exposed by the second photo-mask pattern PM.

Referring to FIGS. 7E and 8E, a conductive pattern CP may be formed on the second seed/barrier layer SL by performing an electroplating process using the second seed/barrier layer SL as an electrode. The conductive pattern CP may fill at least a portion of the via hole VH and may completely fill the recess RS.

Referring to FIGS. 7F and 8F, the second photo-mask pattern PM may be removed. Subsequently, a patterning process may be performed on the second seed/barrier layer SL to form a seed/barrier pattern SP. The patterning process may include a process of etching the second seed/barrier layer SL using the conductive pattern CP as an etch mask. Since the seed/barrier pattern SP is formed, the under bump pattern 130 including the seed/barrier pattern SP and the conductive pattern CP may be formed.

Referring to FIG. 7G, an external connection terminal 180 may be formed on the under bump pattern 130. Next, the second carrier substrate CR2 may be separated from the scaling member 500. The second adhesive layer AD2 may also be removed. The second connection pad 422 of the connection substrate 400 may be exposed. For example, the exposing of the second connection pad 422 may include performing a laser drilling process. A second redistribution pattern 220 and a second insulating layer 210 may be alternately and repeatedly formed on the sealing member 500. The second insulating layer 210 may be formed by substantially the same method as the first insulating layer 110. The second redistribution pattern 220 may be formed by substantially the same method as the first redistribution pattern 120. A bonding pad 230 may be formed to penetrate an uppermost second insulating layer 210T. The bonding pad 230 may be in contact with the second redistribution pattern 220 adjacent thereto in the second direction D2. Next, a second semiconductor package PK2 may be connected onto the first semiconductor package PK1 by using a package connection terminal 680. As a result, a semiconductor package 1000 may be manufactured.

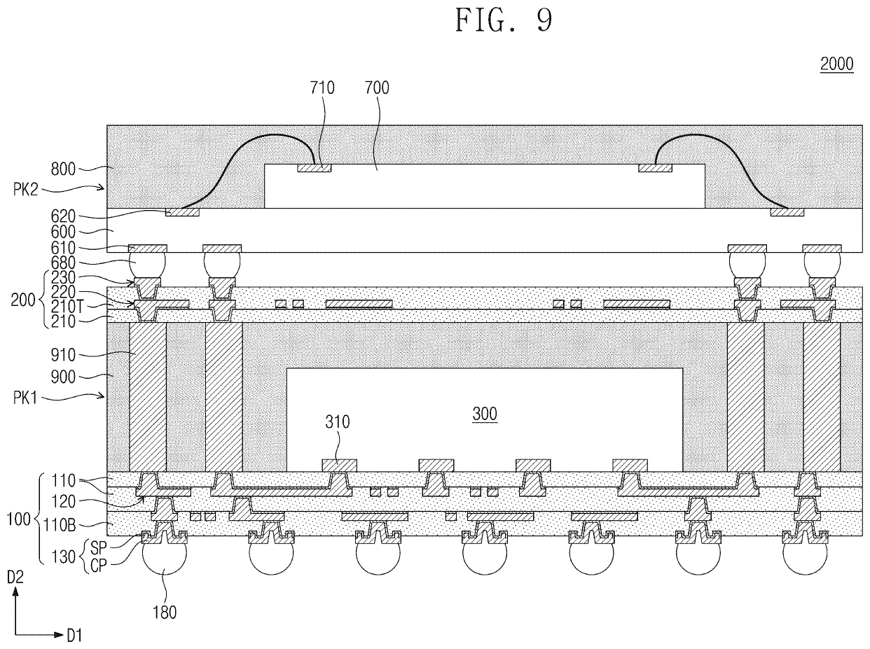

FIG. 9 is a cross-sectional view illustrating a semiconductor package. Hereinafter, the descriptions to the same features as mentioned above will be omitted for the purpose of case and convenience in explanation. Referring to FIG. 9, in some implementations, a semiconductor package 2000 does not include the scaling member 500 and the connection substrate 400. More particularly, a first semiconductor package PK1 may include a molding member 900 instead of the scaling member 500. The first semiconductor package PK1 may include a conductive pillar 910 instead of the connection substrate 400. The molding member 900 may be disposed between the first redistribution substrate 100 and the second redistribution substrate 200. For example, the molding member 900 may include an epoxy molding compound (EMC). The conductive pillar 910 may penetrate the molding member 900 and may be disposed between the first redistribution substrate 100 and the second redistribution substrate 200. The conductive pillar 910 may be spaced apart from the first semiconductor chip 300 in the first direction D1. The conductive pillar 910 may be in contact with the first redistribution pattern 120 and the second redistribution pattern 220. In other words, the conductive pillar 910 may be electrically connected to the first redistribution pattern 120 and the second redistribution pattern 220.

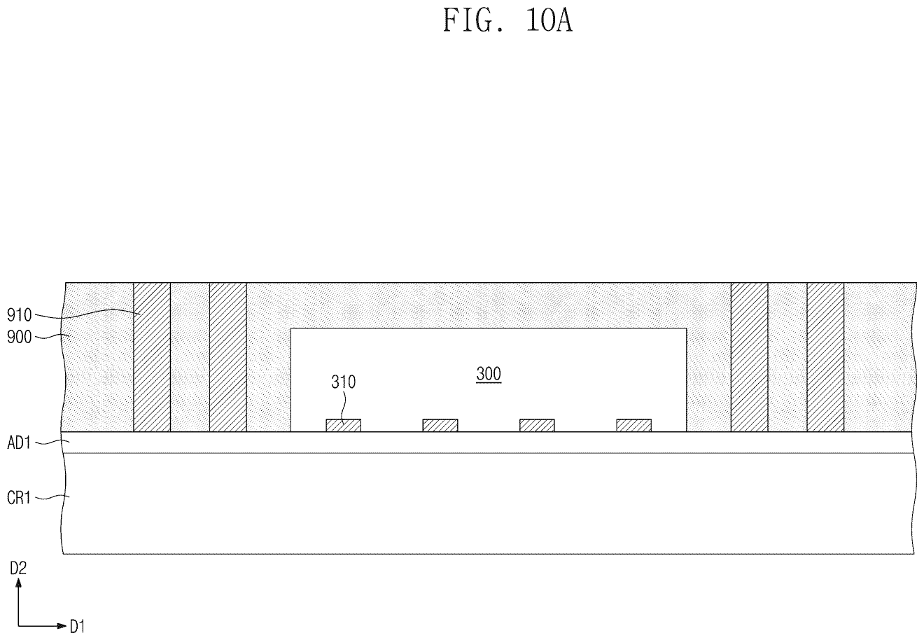

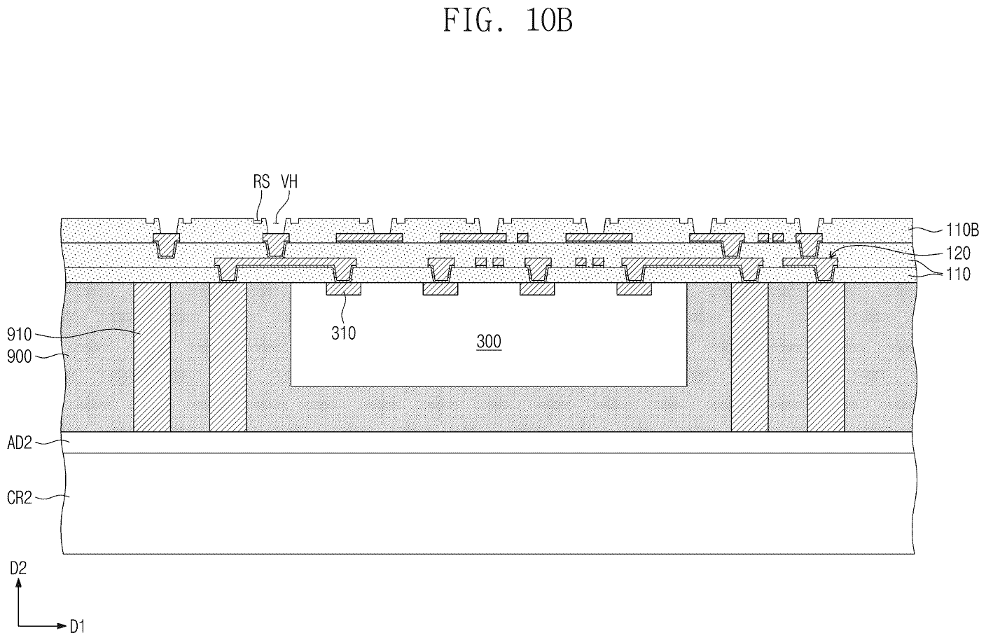

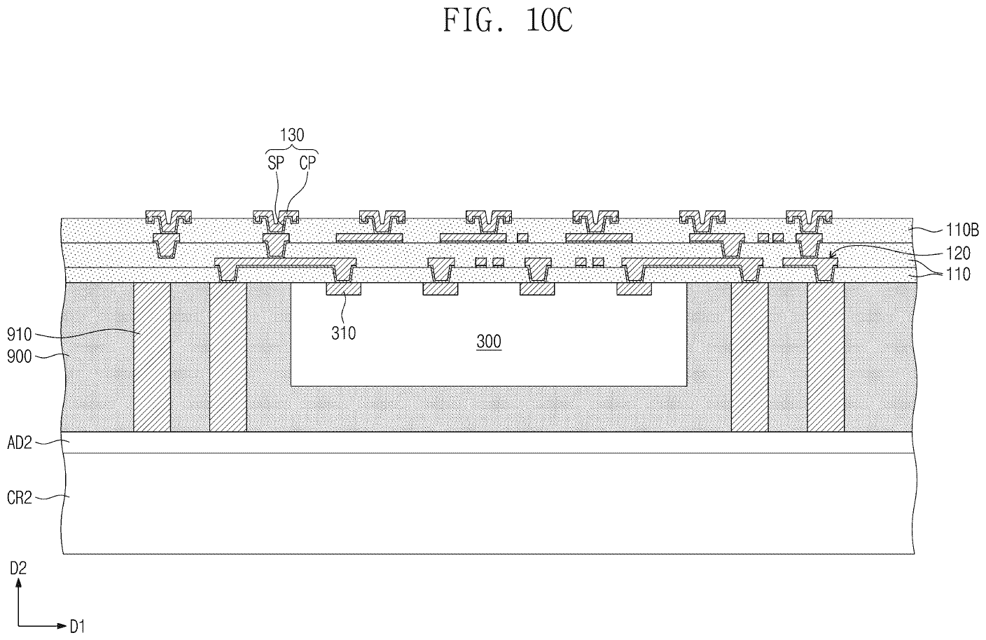

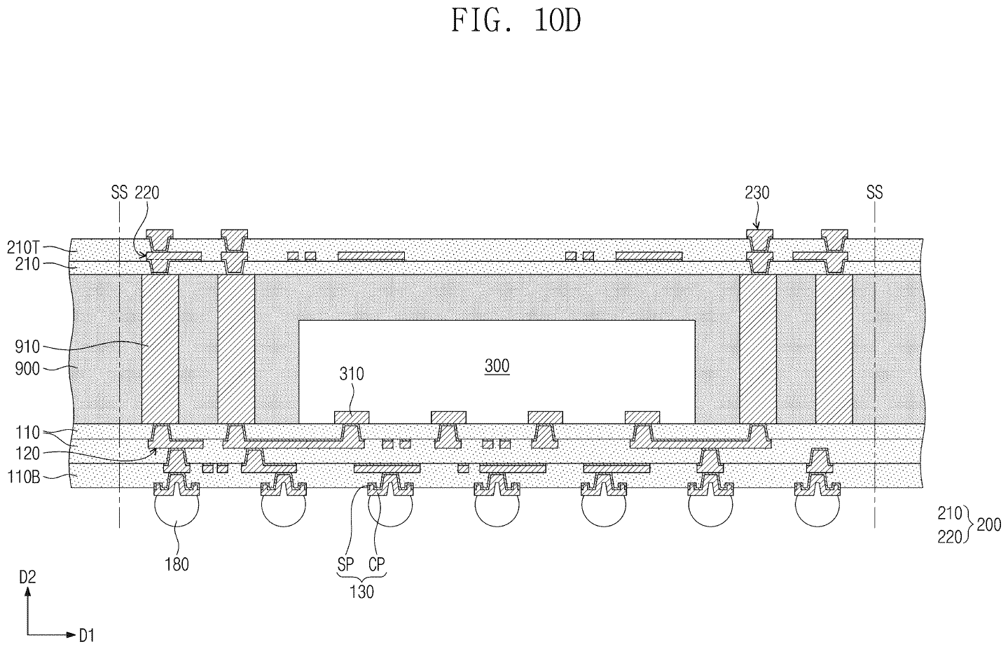

FIGS. 10A, 10B, 10C, and 10D are cross-sectional views illustrating a method of manufacturing a semiconductor package.

Referring to FIG. 10A, a first carrier substrate CR1 having a surface on which a first adhesive layer AD1 is formed may be provided. For example, a conductive pillar 910 may be formed using an electroplating method. A first semiconductor chip 300 may be disposed on the first carrier substrate CR1 and may be spaced apart from the conductive pillar 910 in the first direction D1. Next, a molding member 900 may be formed to fill a space between the first semiconductor chip 300 and the conductive pillar 910 and a space between the conductive pillars 910. In some implementations, a grinding process of exposing a top surface of the conductive pillar 910 may be performed after the formation of the molding member 900.

Referring to FIG. 10B, a second carrier substrate CR2 and a second adhesive layer AD2 are disposed to be in contact with the molding member 900. In addition, the first adhesive layer AD1 and the first carrier substrate CR1 is removed. In this process, the chip pad 310 of the first semiconductor chip 300 and a surface of the conductive pillar 910 may be exposed. First insulating layers 110 and first redistribution patterns 120 may be formed on the first semiconductor chip 300 and the conductive pillar 910. The first insulating layer 110, the first redistribution pattern 120, the via hole VH, and the recess RS may be formed by the same method as described above with reference to FIGS. 7B and 7C.

Referring to FIG. 10C, the under bump pattern 130 and the first redistribution substrate 100 may be formed by the same method as described above with reference to FIGS. 7D, 7E and 7F.

Referring to FIG. 10D, the second redistribution substrate 200 may be formed by the same method as described above with reference to FIG. 7G, and a sawing process may be performed.

Referring again to FIG. 9, the second semiconductor package PK2 may be disposed on the first semiconductor package PK1 to manufacture the semiconductor package 2000.

The semiconductor package may include the under bump pattern disposed on the lowermost insulating layer. The under bump pattern may include the protrusion protruding into the lowermost insulating layer. The protrusion of the under bump pattern may reduce the stress applied to the lowermost insulating layer and may prevent the under bump pattern from being delaminated from the lowermost insulating layer. In other words, reliability of the interface between the under bump pattern and the lowermost insulating layer may be increased to improve the reliability of the semiconductor package.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the embodiments of the inventive concepts have been particularly shown and described, it will be understood by one of ordinary skill in the art that variations in form and detail may be made therein without departing from the spirit and scope of the attached claims.

What is claimed is:

1. A semiconductor package comprising:
a redistribution substrate including a first surface and a second surface, the first surface and the second surface being opposite to each other;
a semiconductor chip disposed on the first surface of the redistribution substrate; and
a connection terminal disposed on the second surface of the redistribution substrate,
wherein the redistribution substrate comprises an insulating layer, a redistribution pattern in the insulating layer, an under bump pattern between the redistribution pattern and the connection terminal,
wherein the under bump pattern includes i) a via portion extending through the insulating layer and connected to the redistribution pattern and ii) a protrusion protruding into the insulating layer.

2. The semiconductor package of claim 1, wherein the via portion has a first height,
wherein the protrusion has a second height, and
wherein the second height is less than the first height.

3. The semiconductor package of claim 2, wherein the second height is greater than ⅛ of the first height.

4. The semiconductor package of claim 1, wherein the via portion and the protrusion are spaced apart from each other in a first direction parallel to the second surface of the redistribution substrate.

5. The semiconductor package of claim 1, wherein the protrusion includes a plurality of protrusions, and
wherein the plurality of protrusions constitute a segmented ring shape.

6. The semiconductor package of claim 5, wherein the under bump pattern further includes a connection portion disposed between the via portion and the plurality of protrusion to connect the via portion and the plurality of protrusion, and
wherein the connection portion includes an extension extending between the plurality of protrusions.

7. The semiconductor package of claim 5, wherein the under bump pattern further includes a connection portion connecting the via portion and the plurality of protrusion,
wherein the connection portion includes:
a first portion disposed between the via portion and the plurality of protrusion;
a second portion spaced apart from the first portion with the plurality of protrusion interposed therebetween; and
an extension extending between the plurality of protrusions,
wherein the extension connects the first portion and the second portion.

8. The semiconductor package of claim 1, wherein the via portion has a first width in a first direction parallel to the second surface of the redistribution substrate,
wherein the plurality of protrusion has a second width in the first direction, and
wherein the second width is less than the first width.

9. The semiconductor package of claim 8, wherein the first width ranges from 130 μm to 170 μm, and
wherein the second width ranges from 10 μm to 15 μm.

10. The semiconductor package of claim 1, further comprising a connection substrate on the first surface of the redistribution substrate,
wherein the connection substrate includes a cavity, and
wherein the semiconductor chip is disposed in the cavity.

11. The semiconductor package of claim 1, further comprising:
a molding member covering the semiconductor chip and the redistribution substrate; and
a conductive pillar extending through the molding member and connected to the redistribution pattern,
wherein the conductive pillar is spaced apart from the semiconductor chip in a first direction parallel to the first surface of the redistribution substrate.

12. The semiconductor package of claim 1, wherein the semiconductor chip comprises a chip pad facing the first surface of the redistribution substrate, and
wherein the chip pad is in contact with the redistribution pattern.

13. The semiconductor package of claim 1, wherein the plurality of protrusion is disposed at an edge of the under bump pattern.

14. The semiconductor package of claim 1, wherein a level of a top surface of the plurality of protrusion is lower than a level of a top surface of the via portion.

15. The semiconductor package of claim 1, wherein the under bump pattern has a W-shape or a W-like shape.

16. A semiconductor package comprising:
a redistribution substrate including a first surface and a second surface, the first surface and the second surface being opposite to each other;
a semiconductor chip on the first surface of the redistribution substrate; and
a connection terminal on the second surface of the redistribution substrate,
wherein the redistribution substrate comprises:
an insulating layer;
a redistribution pattern in the insulating layer; and
an under bump pattern between the redistribution pattern and the connection terminal,
wherein the insulating layer includes:
a via hole exposing the redistribution pattern; and
a recess spaced apart from the via hole in a first direction parallel to the second surface of the redistribution substrate,
wherein the under bump pattern fills the via hole and the recess.

17. The semiconductor package of claim 16, wherein the recess is spaced apart and separate from the redistribution pattern.

18. The semiconductor package of claim 16, wherein a depth of the recess is less than a depth of the via hole and is greater than ⅛ of the depth of the via hole.

19. The semiconductor package of claim 16, wherein a depth of the via hole ranges from 20 μm to 30 μm, and
wherein a depth of the recess ranges from 4 μm to 24 μm.

20. A semiconductor package comprising:
a lower semiconductor package; and
an upper semiconductor package on the lower semiconductor package,
wherein the lower semiconductor package comprises:
a lower redistribution substrate;
an upper redistribution substrate on the lower redistribution substrate; and
a semiconductor chip between the lower redistribution substrate and the upper redistribution substrate,
wherein the lower redistribution substrate comprises:
a plurality of insulating layers;
redistribution patterns disposed in the insulating layers; and
an under bump metal (UBM) disposed on a lowermost insulating layer of the plurality of insulating layers,
wherein the under bump metal comprises:
a seed/barrier pattern; and
a conductive pattern on the seed/barrier pattern,
wherein the under bump metal includes: a via portion extending through the lowermost insulating layer and in contact with one of the redistribution patterns, which is adjacent thereto in a vertical direction; and a protrusion protruding into the lowermost insulating layer,
wherein the protrusion is spaced apart from the one redistribution pattern, and
wherein a height of the protrusion is less than a height of the via portion.
